(19) United States
(12) Patent Application Publication
(10) Pub. No.: US 2010/0258433 A1
(43) Pub. Date: Oct. 14, 2010

(54) FILM FORMING METHOD AND FILM FORMING APPARATUS FOR TRANSPARENT ELECTRICALLY CONDUCTIVE FILM

(75) Inventors: Hirohisa Takahashi, Sanmu-shi (JP); Satoru Ishibashi, Sanmu-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Chigasaki-shi (JP)

(21) Appl. No.: 12/808,006

(22) PCT Filed: Dec. 17, 2008
(86) PCT No.: PCT/JP2008/073002

§ 371 Date: Jun. 14, 2010

(30) Foreign Application Priority Data
Dec. 28, 2007 (JP) 2007-340913

(51) Int. Cl. C23C 14/08; C23C 14/34; C23C 14/35; H01B 13/00

(52) U.S. Cl. 204/192.17; 204/298.13

(57) ABSTRACT

A film forming method for a transparent electrically conductive film that forms a zinc oxide-based transparent electrically conductive film on a substrate by sputtering using a target containing a zinc oxide-based material, performing the sputtering in a reactive gas atmosphere that contains two types or three types selected from among a group consisting of hydrogen gas, oxygen gas and water vapor.

### TECHNICAL FIELD

The present invention relates to a film forming method and a film forming apparatus for a transparent electrically conductive film. More specifically, it relates to a preferred film forming method and a film forming apparatus used in various devices in the optoelectronics field, such as a flat panel display (FPD), touch panel, photovoltaic cell, electromagnetic shield, antireflection (AR), membrane, light emitting diode (LED).

Priority is claimed on Japanese Patent Application No. 2007-340913, filed Dec. 28, 2007, the content of which is incorporated herein by reference.

### BACKGROUND ART

Conventionally, as an electrode material in a photovoltaic cell or light emitting diode, there has been indium tin oxide (ITO) in which tin oxide is added to indium oxide in an amount of 5 to 10 percent by weight, and it is utilized as a transparent electrically conductive material.

However, indium (In), which is the raw material of ITO, is a rare metal, and it is expected in the future to increase in cost as it becomes harder to obtain. Therefore, zinc oxide (ZnO)-based materials, which are abundant and inexpensive, are attracting attention as a transparent electrically conductive material in place of ITO (for example, refer to Patent Document 1).

ZnO-based materials are an N-type semiconductor exhibiting electrical conductivity by discharging free electrons as a result of oxygen vacancies being formed in the ZnO crystal by a few shifts from the stoichiometric constitution by slightly reducing the ZnO, or by discharging free electrons as a result of becoming ions by B, Al, Ga added as an impurity intruding into positions of Zn ions in the ZnO crystal lattice.

ZnO-based materials are suited to sputtering in which uniform film formation over a large substrate is possible, and film formation is possible by changing a target composed of an In₂O₃-based material such as ITO to a target composed of a ZnO-based material. Also, since a ZnO-based material does not include highly insulating low-grade oxides (InO) such as In₂O₃-based materials, anomalies in sputtering hardly occur.

[Patent Document 1] Japanese Unexamined Patent Application No. H09-87833

### DISCLOSURE OF THE INVENTION

### Problem That the Invention to Solve

Although the transparency of a conventional transparent electrically conductive film composed of a ZnO-based material compares favorably with a conventional ITO film, there is the problem of its specific resistance being higher than an ITO film.

Therefore, in order to lower the specific resistance of a ZnO-based transparent electrically conductive film to the desired value, a method is considered that consists of introducing hydrogen gas as a reducing gas to the chamber during sputtering, and performing film formation in this reducing gas atmosphere.

However, in this case, although the specific resistance of the obtained transparent electrically conductive film does indeed decrease, a slight amount of metallic luster is produced on the surface thereof, giving rise to the problem of a reduction in transmittance.

The present invention was achieved in order to solve the abovementioned issues, and has as its object to provide a film forming method and film forming apparatus for a transparent electrically conductive film that lowers the specific resistance of a ZnO-based transparent electrically conductive film and can maintain the transparency with respect to visible light rays.

### Means for Solving the Problem

The present inventors conducted extensive investigations into a method of forming a transparent electrically conductive film using a ZnO-based material. As a result, the present inventors perfected the present invention by discovering that, when forming a zinc oxide-based transparent electrically conductive film by a sputtering method using a target that consists of a zinc oxide-based material, if sputtering is performed in a reactive gas atmosphere that contains two types or three types that are selected from among a group consisting of hydrogen gas, oxygen gas, and water vapor, and moreover sputtering is performed under the condition of a ratio R (P_{H2}/P_{O2}) of the partial pressure of the hydrogen gas (P_{H2}) to the partial pressure of the oxygen gas (P_{O2}) satisfying

R=P_{H2}/P_{O2}≧5 (1)

it is possible to lower the specific resistance of a zinc oxide-based transparent electrically conductive film, and moreover possible to maintain the transparency with respect to visible light rays.

More specifically, the film forming method for a transparent electrically conductive film of the present invention is a film forming method for a transparent electrically conductive film that forms a zinc oxide-based transparent electrically conductive film on a substrate by sputtering using a target that contains a zinc oxide-based material, the method performing the sputtering in a reactive gas atmosphere that contains two types or three types selected from among a group consisting of hydrogen gas, oxygen gas and water vapor.

In this film forming method, when forming a transparent electrically conductive film on a substrate by a sputtering method, sputtering is performed in a reactive gas atmosphere that includes two types or three types that are selected from the group of hydrogen gas, oxygen gas, and water vapor. Thereby, it is possible to make the atmosphere when forming a zinc oxide-based transparent electrically conductive film on a substrate by sputtering an atmosphere that includes two types or three types that are selected from among a group consisting of hydrogen gas, oxygen gas and water vapor, that is, an atmosphere in which the ratio of the reducing gas to the oxidizing gas is well proportioned. Thereby, if sputtering is performed in this atmosphere, the transparent electrically conductive film that is obtained, as a result of the number of oxygen vacancies in the zinc oxide crystal being controlled, becomes a film that has a desired conductivity, and the specific resistance thereof also decreases and becomes a desired specific resistance value.

Also, it is possible to maintain the transparency with respect to visible light rays of the transparent electrically conductive film that is obtained without metallic luster being produced.

When performing the sputtering, in the case of including at least the hydrogen gas and the oxygen gas in the atmosphere, a ratio R (P_{H2}/P_{O2}) of the partial pressure of the hydrogen gas (P_{H2}) to the partial pressure of the oxygen gas (P_{O2}) may satisfy Equation (2) below.

R=P_{H2}/P_{O2}≦5 (2)

When performing the sputtering, the sputtering voltage that is applied to the target may be 340 V or less.

When performing the sputtering, a sputtering voltage composed of a high frequency voltage superimposed on a direct current voltage may be applied to the target.

When performing the sputtering, the maximum value of the strength of the horizontal magnetic field at the surface of the target may be 600 Gauss or more.

The zinc oxide-based material may be aluminum-doped zinc oxide or gallium-doped zinc oxide.

A film forming apparatus for a transparent electrically conductive film of the present invention is a film forming apparatus for a transparent electrically conductive film that, by using a target containing a zinc oxide-based material, forms a zinc oxide-based transparent electrically conductive film on a substrate that is arranged facing this target, provided with a vacuum container; at least two of a hydrogen gas introduction unit, an oxygen gas introduction unit, and a water vapor introduction unit that are provided in this vacuum container; a target holding unit that holds the target in the vacuum container; and a power supply that applies a sputtering voltage to the target.

In this film forming apparatus, the vacuum container is provided with two or more of a hydrogen gas introduction unit, an oxygen gas introduction unit, and a water vapor introduction unit, whereby by using a target comprising a zinc oxide-based material, it is possible to make the atmosphere when forming a zinc oxide-based transparent electrically conductive film on a substrate by a sputtering method a reactive gas atmosphere in which the ratio of the reducing gas to the oxidizing gas is well proportioned by using two among the hydrogen gas introduction unit, the oxygen gas introduction unit, and the water vapor introduction unit. Thereby, as a result of the number of oxygen vacancies in the zinc oxide crystal being controlled, it is possible to form a zinc oxide-based transparent electrically conductive film in which the specific resistance decreases, no metallic luster is produced, and is capable of maintaining transparency with respect to visible light rays.

The power supply may serve as a direct current power supply and a high frequency power supply.

In this film forming apparatus, by combining the direct current voltage and the high frequency voltage, it is possible to lower the sputtering voltage. Thereby, it becomes possible to form a zinc oxide-based transparent electrically conductive film in which the crystal lattice is organized, and the specific resistance of the obtained transparent electrically conductive film is also low.

The target holding unit may be provided with a magnetic field generating unit that generates a horizontal magnetic field of which the maximum value of the strength at the surface of the target is 600 Gauss or more.

In this film forming apparatus, by providing a magnetic field generating unit that generates a horizontal magnetic field of which the maximum value of the strength at the surface of the target is 600 Gauss or more, high density plasma is generated at a position at which the vertical magnetic field at the surface of the target becomes 0 (the horizontal magnetic field is a maximum). Thereby it becomes possible to form a zinc oxide-based transparent electrically conductive film with an organized crystal lattice.

### EFFECT OF THE INVENTION

Since the film forming method for a transparent electrically conductive film of the present invention performs sputtering in a reactive gas atmosphere that contains two types or three types that are selected from the group of hydrogen gas, oxygen gas, and water vapor, it is possible to lower the specific resistance of the zinc oxide-based transparent electrically conductive film, and moreover it is possible to maintain the transparency with respect to visible light rays.

Accordingly, it is possible to readily form a zinc oxide-based transparent electrically conductive film with low specific resistance and excellent transparency with respect to visible light rays.

Since the film forming apparatus for a transparent electrically conductive film of the present invention provides the vacuum container with two or more of a hydrogen gas introduction unit, an oxygen gas introduction unit, and a water vapor introduction unit, by controlling them it is possible to make the atmosphere when forming a zinc oxide-based transparent electrically conductive film in the vacuum container a reactive gas atmosphere in which the ratio of the reducing gas to the oxidizing gas is well proportioned.

Accordingly, just by modifying a portion of a conventional film forming apparatus, it is possible to form a zinc oxide-based transparent electrically conductive film with low specific resistance and excellent transparency with respect to visible light rays.

### BRIEF DESCRIPTION OF THE DRAWINGS

FIG. 1 is a schematic configuration drawing (plan view) that shows the sputtering apparatus of the first embodiment of the present invention.

FIG. 2 is a plan cross-sectional view that shows the essential portions of the film forming chamber of the sputtering apparatus of the same embodiment.

FIG. 3 is a graph that shows the effect of H₂O gas (water vapor) in non-thermal film formation.

FIG. 4 is a graph that shows the effect of H₂O gas (water vapor) in thermal film formation in which the reference temperature has been raised 250° C.

FIG. 5 is a graph that shows the effect in the case of simultaneously introducing H₂ gas and O₂ gas during thermal film forming in which the substrate temperature has been raised to 250° C.

FIG. 6 is a graph that shows the effect in the case of simultaneously introducing H₂ gas and O₂ gas during thermal film forming in which the substrate temperature has been raised to 250° C.

FIG. 7 is a graph that shows the effect of H₂ gas in non-thermal film formation.

FIG. 8 is a plan cross-sectional view that shows the essential portions of the film forming chamber of an interback-type magnetron sputtering apparatus of the second embodiment of the present invention.

### DESCRIPTION OF REFERENCE NUMERALS

1 sputtering apparatus
2 preparation/ejection chamber
3 film forming chamber
4 rough exhaust unit
5 substrate tray
6 substrate
7 target
11 heater
12 cathode
13 high vacuum exhaust unit
14 power supply
15 gas introduction unit
15a sputtering gas introduction unit
15b hydrogen gas introduction unit
15c oxygen gas introduction unit
15d water vapor introduction unit
21 magnetron sputtering apparatus
22 sputtering cathode mechanism
23 back plate
24 magnetic circuit
24a, 24b magnetic circuit units
25 bracket
26 first magnet
27 second magnet
28 yoke
29 magnetic lines of force
30 position at which the vertical magnetic field becomes 0

### BEST MODE FOR CARRYING OUT THE INVENTION

The best modes for carrying out the film forming method and film forming apparatus for a transparent electrically conductive film of the present invention shall be described.

Note that this mode is one described in a concrete manner for better understanding the gist of the present invention, and unless otherwise stated should not be deemed to limit the present invention.

### First Embodiment

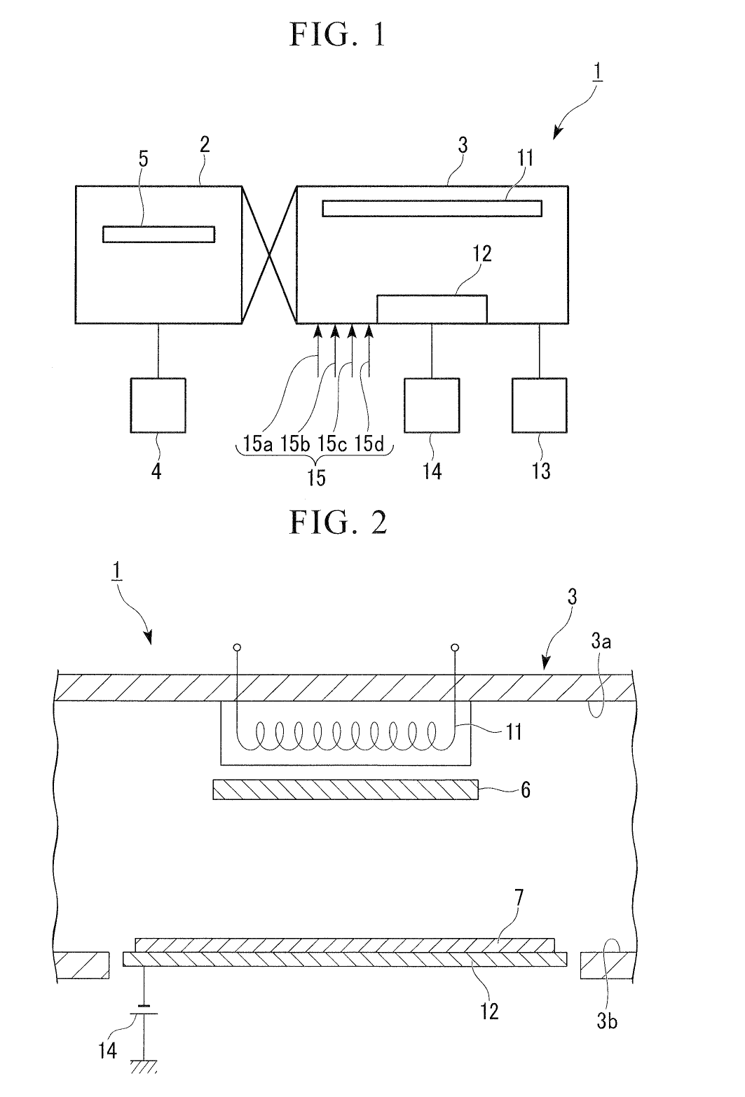

FIG. 1 is a schematic configuration drawing (plan view) that shows the sputtering apparatus (film forming apparatus) of the first embodiment of the present invention, and FIG. 2 is a plan cross-sectional view that shows the essential portions of the film forming chamber of the same sputtering apparatus.

This sputtering apparatus 1 is an interback-type sputtering apparatus, and is provided with a preparation/ejection chamber 2 that for example carries in/carries out a substrate such as an alkali-free glass substrate (not illustrated), and a film forming chamber (vacuum container) 3 in which a zinc oxide-based transparent electrically conductive film is formed on the substrate.

In the preparation/ejection chamber 2 is provided a rough exhaust unit 4 such as a rotary pump or the like that performs rough vacuuming of this chamber. Also, a substrate tray 5 for holding/moving a substrate is disposed in a movable manner in the chamber of the preparation/ejection chamber 2.

A heater 11 that heats a substrate 6 is provided longitudinally on one side surface 3a of the film forming chamber 3. A target 7 of a zinc oxide-based material is held on the other side surface 3b of the film forming chamber 3, and a cathode (target holding unit) 12 for applying a desired sputtering voltage is longitudinally provided on this target 7. Moreover, in the film forming chamber 3 are provided a high vacuum exhaust unit 13 such as a turbo molecule pump that performs high vacuuming of this chamber, a power supply 14 that applies a sputtering voltage on the target 7, and a gas introduction unit 15 that introduces gas into this chamber.

The cathode 12 consists of a plate-shaped metal plate, and the target 7 is fixed by bonding (fixing) with a brazing material or the like.

The power supply 14 is one that applies a sputtering voltage in which a high-frequency voltage is superimposed on a direct current voltage to the target 7, and is provided with a direct current (DC) power supply and a high frequency (RF) power supply (not illustrated).

The gas introduction unit 15 is provided with a sputtering gas introduction unit 15a that introduces sputtering gas such as argon, a hydrogen gas introduction unit 15b that introduces hydrogen gas, an oxygen gas introduction unit 15c that introduces oxygen gas, and a water vapor introduction unit 15d that introduces water vapor.

Note that in this gas introduction unit 15, the hydrogen gas introduction unit 15b, the oxygen gas introduction unit 15c, and the water vapor introduction unit 15d are selected as the need arises. For example, two unit may be selected and used such as “the hydrogen gas introduction unit 15b and the oxygen gas introduction unit 15c”, “the hydrogen gas introduction unit 15b and the water vapor introduction unit 15d”.

Next, the method of forming the zinc oxide-based transparent electrically conductive film on the substrate using the aforementioned sputtering apparatus 1 shall be described.

First, the target 7 is fixed to the cathode 12 by bonding with a brazing material or the like. Here, a zinc oxide-based material, for example aluminum-doped zinc oxide (AZO) in which aluminum oxide (Al₂O₃) is added in an amount of 0.1 to 10 percent by weight, and gallium-doped zinc oxide (GZO) in which gallium oxide (Ga₂O₃) is added in an amount of 0.1 to 10 percent by weight, is used in the target material. Among these, aluminum-doped zinc oxide (AZO) is preferred on the point of being capable of forming a thin film with a lower specific resistance.

Next, the substrate 6 is stored on the substrate tray 5 of the preparation/ejection chamber 2, and the preparation/ejection chamber 2 and the film forming chamber 3 are pumped to a rough vacuum by the rough exhaust unit 4 until reaching a predetermined degree of vacuum, for example 0.27 Pa (2.0×10⁻³ Torr). Then, the substrate 6 is carried into the film forming chamber 3 from the preparation/ejection chamber 2, and this substrate 6 is disposed in front of the heater 11, which is in the state of the setting being OFF, so as to face the target 7. The substrate 6 is heated by the heater 11 so as to be in a temperature range of 100° C. to 600° C.

Next, the film forming chamber 3 is pumped to a high vacuum by the high vacuum exhaust unit 13 until reaching a predetermined high degree of vacuum, for example, 2.7×10⁻⁴ Pa (2.0×10⁻⁶ Ton). Then, sputtering gas such as Ar or the like is introduced to the film forming chamber 3 by the sputtering gas introduction unit 15a, and two types or three types of gases that are selected from the group of hydrogen gas, oxygen gas, and water vapor are introduced using at least two among the hydrogen gas introduction unit 15b, the oxygen gas introduction unit 15c, and the water vapor introduction unit 15d.

Here, in the case of having selected hydrogen gas and oxygen gas, the ratio R (P_{H2}/P_{O2}) of the partial pressure of hydrogen gas (P_{H2}) and the partial pressure of oxygen gas (P_{O2}) preferably satisfies

R=P_{H2}/P_{O2}≧5 (3)

Thereby, the atmosphere in the film forming chamber 3 becomes a reactive gas atmosphere in which the hydrogen gas density is 5 times or more the oxygen gas density, and by this reactive gas atmosphere satisfying R=P_{H2}/P_{O2}≧5, a transparent electrically conductive film with a specific resistance of 1.0×10³ μΩ·cm or less is obtained.

Also, in the case of having selected hydrogen gas and water vapor (gas), the ratio R (P_{H2}/P_{H2O}) of the partial pressure of hydrogen gas (P_{H2}) and the partial pressure of water vapor (gas) (P_{H2O}) preferably satisfies

R=P_{H2}/P_{H2O}≧5 (4)

Thereby, the atmosphere in the film forming chamber 3 becomes a reactive gas atmosphere in which the hydrogen gas density is 5 times or more the oxygen gas density, and by this reactive gas atmosphere satisfying R=P_{H2}/P_{H2O}≧5, a transparent electrically conductive film with a specific resistance of 1.0×10³ μΩ·cm or less is obtained.

Next, a sputtering voltage is applied to the target 7 with the power supply 14.

It is preferably that this sputtering voltage be 340 V or less. By lowering the discharge voltage, it becomes possible to form a zinc oxide-based transparent electrically conductive film in which the crystal lattice is organized, and the specific resistance of the obtained transparent electrically conductive film is also low.

As for this sputtering voltage, it is preferable to superimpose a high-frequency voltage on a direct current voltage. By superimposing a high-frequency voltage on a direct current voltage, it is possible to further lower the discharge voltage.

By the application of the sputtering voltage, plasma is generated on the substrate 6, and ions of the sputtering gas such as Ar that are excided by this plasma collide with the target 7. As a result of this collision, the atoms that constitute the zinc oxide-based material such as aluminum-doped zinc oxide (AZO) and gallium-doped zinc oxide (GZO) fly out from the target 7, and form a transparent electrically conductive film that consists of the zinc oxide-based material on the substrate 6.

In this film forming process, the atmosphere in the film forming chamber 3 becomes a reactive gas atmosphere consisting of two or three types or more that are selected from the group of hydrogen gas, oxygen gas, and water vapor. Therefore, it is possible to obtain a transparent electrically conductive film in which the number of oxygen vacancies in the zinc oxide crystal are controlled by sputtering that is performed in this reactive gas atmosphere. As a result, since the specific resistance thereof also declines, it is possible to obtain a transparent electrically conductive film that has the desired electrical conductivity and specific resistance.

In particular, in the case of the hydrogen gas density being five times or more the oxygen gas density in the film forming chamber 3, a reactive gas atmosphere results in which the ratio of the hydrogen gas and the oxygen gas is balanced. It is possible to obtain a transparent electrically conductive film in which the number of oxygen vacancies in the zinc oxide crystal are highly controlled by sputtering that is performed in this reactive gas atmosphere. As a result, since the specific resistance thereof also declines to be equivalent to that of an ITO film, it is possible to obtain a transparent electrically conductive film that has the desired electrical conductivity and specific resistance.

Also, there is no metallic luster in the obtained transparent electrically conductive film, and the transparency with respect to visible light rays is maintained.

Next, this substrate 6 is transported from the film forming chamber 3 to the preparation/ejection chamber 2, the vacuum of the preparation/ejection chamber 2 is broken, and the substrate 6 on which this zinc oxide-based transparent electrically conductive film is formed is taken out.

In this manner, the substrate 6 is obtained on which a zinc oxide-based transparent electrically conductive film is formed having low specific resistance and good transparency with respect to visible light rays.

Next, the results of experiments performed by the present inventors for the film forming method of a zinc oxide-based transparent electrically conductive film of the present embodiment shall be described.

An aluminum-doped zinc oxide (AZO) target measuring 5 inches×16 inches is used in which aluminum oxide (Al₂O₃) is added in an amount of 2 percent by weight. This target is fixed by a brazing material to the parallel plate-type cathode 12 that applies a direct current voltage. Next, an alkali-free glass substrate is placed in the preparation/ejection chamber 2, and the preparation/ejection chamber 2 is pumped to a rough vacuum by the rough exhaust unit 4. Next, this alkali-free glass substrate is carried into the film forming chamber 3, which has been pumped to a high vacuum by the high vacuum exhaust unit 13, and is disposed to face the AZO target.

Next, after introducing argon gas to a pressure of 5 m Ton by the gas introduction unit 15, H₂O gas is introduced to a partial pressure of 5×10⁻⁵ Ton, or O₂ gas is supplied to a partial pressure of 1×10⁻⁵ Ton. Then, in the atmosphere of the H₂O gas or the O₂ gas, a voltage of 1 kW is applied to the cathode 12 by the power supply 14, whereby the AZO target that is attached to the cathode 12 is sputtered, and an AZO film is deposited on the alkali-free glass substrate.

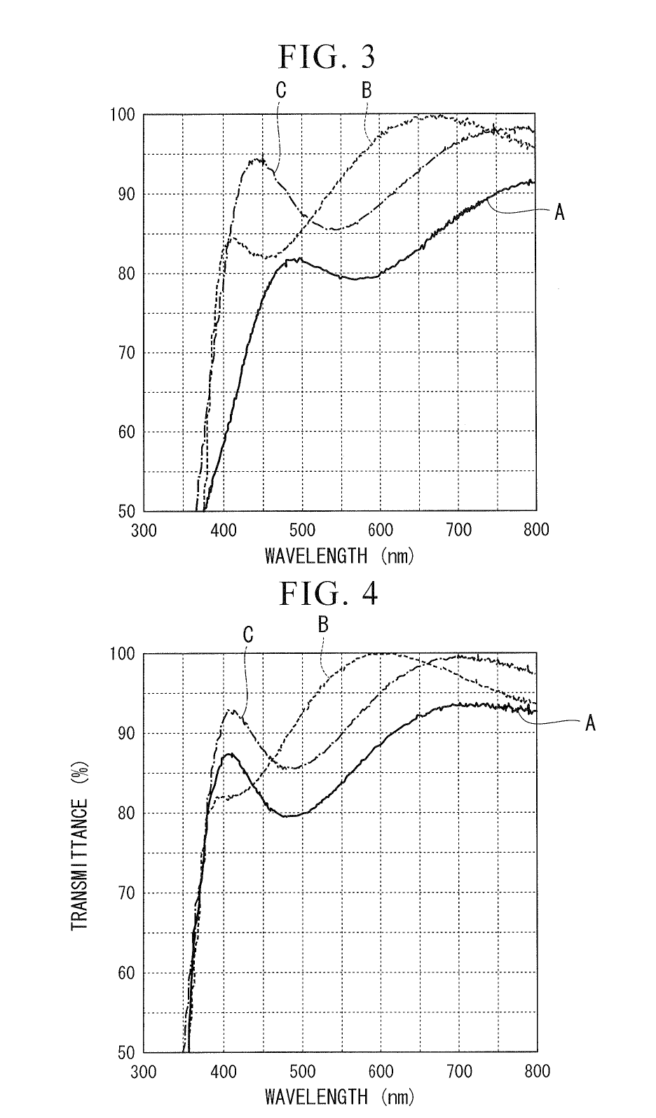

FIG. 3 is a graph that shows the effect of H₂O gas (water vapor) in non-thermal film formation. In FIG. 3, A denotes the transmittance of a zinc oxide-based transparent electrically conductive film in the case of not introducing a reactive gas, B denotes the transmittance of a zinc oxide-based transparent electrically conductive film in the case of introducing H₂O gas so that the partial pressure thereof becomes 5×10⁻⁵ Ton, and C denotes the transmittance of a zinc oxide-based transparent electrically conductive film in the case of introducing O₂ gas so that the partial pressure thereof becomes 1×10⁻⁵ Ton.

In the case of not introducing a reactive gas, the film thickness of the transparent electrically conductive film was 207.9 nm, and the specific resistance was 1576 μΩ·cm.

Also, in the case of introducing H₂O gas, the film thickness of the transparent electrically conductive film was 204.0 nm, and the specific resistance was 64464 μΩ·cm.

Also, in the case of introducing O₂ gas, the film thickness of the transparent electrically conductive film was 208.5 nm, and the specific resistance was 2406 μΩ·cm.

According to FIG. 3, it was found that it is possible to change the peak wavelength of transmittance without changing the film thickness by introducing H₂O gas. Also, compared to A that does not introduce a reactive gas, in B that introduced H₂O gas, the transmittance increased overall.

Also, in the case of having introduced H₂O gas, the specific resistance is high and the resistance degradation becomes large, but the transmittance is high. That is, it was found that the transparent electrically conductive film that is obtained in this case can be applied to optical members in which a low resistance is not required, such as antireflection films and the like.

Moreover, it was found that by repeating film forming by the conditions of not introducing and introducing H₂O, or changing the introduction amount, an optical device with a laminated structure in which the refraction index changes for each layer is obtained on one target.

Also, in a buffer layer of a photoelectric cell or an intermediate electrode with a tandem structure, the film thickness is thin, and since current flows in the film thickness direction, the requirement for low resistance is week. In contrast, in the case of adjusting the peak of the wavelength of light that is transmitted, the peak wavelength of transmittance is changed without changing the film thickness by the introduction amount of the H₂O gas by the film forming method of the transparent electrically conductive film of the present invention. Thereby, it is possible to form a buffer layer and an intermediate electrode that transmitted light of the desired wavelength.

Moreover, in the case of the transparent electrically conductive film of the present invention being used for an element that emits a specified wavelength such as an LED or organic EL illumination, it is possible to adjust the transmittance of the transparent electrically conductive film so that transmittance at the light-emitting wavelength becomes a maximum.

Next, an AZO film was deposited on the alkali-free glass substrate in the same manner as described above except for heating the alkali-free glass substrate to 250° C.

FIG. 4 is a graph that shows the effect of H₂O gas (water vapor) in thermal film formation in which the reference temperature is assumed to be 250° C. In FIG. 4, A denotes the transmittance of a zinc oxide-based transparent electrically conductive film in the case of not introducing a reactive gas, B denotes the transmittance of a zinc oxide-based transparent electrically conductive film in the case of introducing H₂O gas so that the partial pressure thereof becomes 5×10⁻⁵ Ton, and C denotes the transmittance of a zinc oxide-based transparent electrically conductive film in the case of introducing O₂ gas so that the partial pressure thereof becomes 1×10⁻⁵ Ton. Note that a parallel plate-type cathode that applies a direct current (DC) voltage was used.

In the case of not introducing a reactive gas, the film thickness of the transparent electrically conductive film was 201.6 nm, and the specific resistance was 766 μΩ·cm.

Also, in the case of introducing H₂O gas, the film thickness of the transparent electrically conductive film was 183.0 nm, and the specific resistance was 6625 μΩ·cm.

Also, in the case of introducing O₂ gas, the film thickness of the transparent electrically conductive film was 197.3 nm, and the specific resistance was 2214 μΩ·cm.

According to FIG. 4, it was found that the same effect as non-thermal film formation was obtained in the thermal film formation.

In the case of introducing H₂O gas, although the film thickness became somewhat thinner, it was found that the peak wavelength shifted by an amount equal to or greater than the shift of the peak wavelength due to the interference of the film thickness. That is, it was found that even for the case of raising the substrate temperature to 250° C., the same effect as the case of not applying heat is obtained.

Next, an AZO film was deposited on an alkali-free glass substrate under the same conditions as described above, except for replacing the H₂O gas with H₂ gas, using a parallel plate-type cathode that is capable of superimposing a high frequency (RF) voltage on a direct current (DC) voltage, applying sputtering power that consists of 350 W high frequency (RF) power superimposed on 1 kW DC power to the cathode 12 by the power supply 14, and with 4A constant current control.

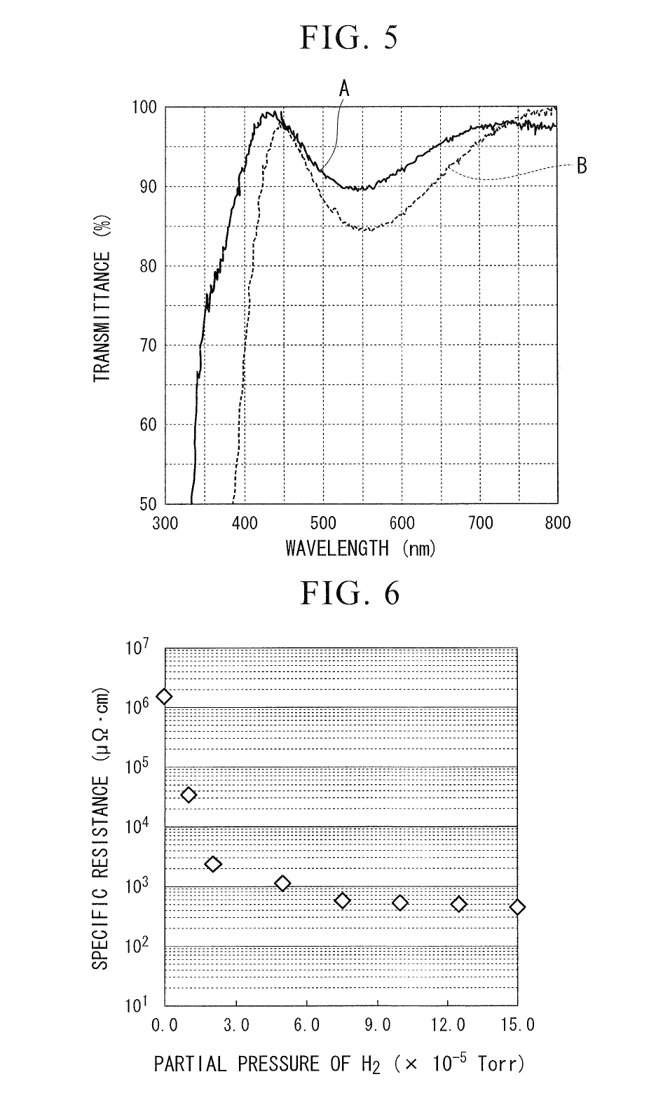

FIG. 5 is a graph that shows the effect in the case of simultaneously introducing H₂ gas and O₂ gas during thermal film forming in which the substrate temperature has been raised to 250° C. In FIG. 5, A denotes the transmittance of a zinc oxide-based transparent electrically conductive film in the case of simultaneously introducing H₂ gas and O₂ gas so that the partial pressure of the H₂ gas becomes 15×10⁻⁵ Ton and the partial pressure of the O₂ gas becomes 1×10⁻⁵ Ton, and B denotes the transmittance of a zinc oxide-based transparent electrically conductive film in the case of introducing O₂ gas so that the partial pressure thereof becomes 1×10⁻⁵ Ton.

In the case of simultaneously introducing H₂ gas and O₂ gas, the film thickness of the transparent electrically conductive film was 211.1 nm.

Also, in the case of introducing O₂ gas only, the film thickness of the transparent electrically conductive film was 208.9 nm.

According to FIG. 5, it was found that in the case of simultaneously introducing H₂ gas and O₂ gas, the peak wavelength shifted by an amount equal to or greater than the shift of the peak wavelength due to the interference of the film thickness, compared to case of introducing only O₂ gas. There was also found to be an improvement in the transmittance compared to the case of introducing only O₂ gas.

FIG. 6 is a graph that shows the effect in the case of simultaneously introducing H₂ gas and O₂ gas during thermal film forming in which the substrate temperature has been raised to 250° C. It shows the specific resistance of a zinc oxide-based transparent electrically conductive film in the case of the partial pressure of the O₂ gas being fixed at 1×10⁻⁵ Ton (partial pressure of flow conversion), and the partial pressure of the H₂ gas being altered between 0 to 15×10⁻⁵ Ton (partial pressure of flow conversion). Note that the film thickness of the obtained transparent electrically conductive film was mostly 200 nm.

According to this graph, although the specific resistance rapidly decreased in the range of the partial pressure of the H₂ gas from 0 Ton to 2.0×10⁻⁵ Ton, the specific resistance was found to be stable when the partial pressure of the H₂ gas exceeded 2.0×10⁻⁵ Ton.

Since the specific resistance of the transparent electrically conductive film in the case of not introducing a reactive gas under the same conditions is 422 μΩ·cm, in the case of simultaneously introducing H₂ gas and O₂ gas, it was found that the degradation in the specific resistance was small.

In particular, in transparent electrically conductive films to be used in displays and the like, in addition to the transmittance in the visible light region being high, low resistance is also required. That of 1.0×10³ μΩ·cm or less is required in transparent electrodes for ordinary displays. In FIG. 6, the specific resistance is 1.0×10³ μΩ·cm or less when the pressure of H₂ gas is 5.0×10⁻⁵ Ton or more. Since the O₂ gas pressure is 1×10⁻⁵ Ton, in order to make the specific resistance 1.0×10³ μΩ·cm or less, it is preferable to have R=P_{H2}/P_{O2}≧5.

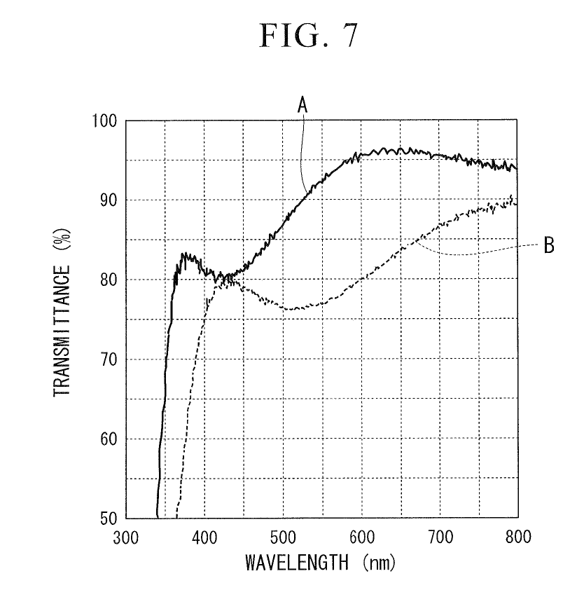

FIG. 7 is a graph that shows the effect of H₂ gas in non-thermal film formation. In FIG. 7, A denotes the transmittance of a zinc oxide-based transparent electrically conductive film in the case of introducing H₂ gas so that the partial pressure thereof becomes 3×10⁻⁵ Ton and B denotes the transmittance of a zinc oxide-based transparent electrically conductive film in the case of introducing O₂ gas so that the partial pressure thereof becomes 1.125×10⁻⁵ Ton. Note that a facing-type cathode that applies a direct current (DC) voltage was used.

In the case of introducing H₂ gas, the film thickness of the transparent electrically conductive film was 191.5 nm, and the specific resistance was 913 μΩ·cm.

Also, in the case of introducing 0₂ gas, the film thickness of the transparent electrically conductive film was 206.4 nm, and the specific resistance was 3608 μΩ·cm.

According to FIG. 7, it was found that it is possible to change the peak wavelength of transmittance without changing the film thickness by introducing H₂ gas.

Also, it was found that the transmittance in the case of having introduced H₂ gas is high compared to the case of having introduced O₂ gas.

From the above, it was found that a zinc oxide-based transparent electrically conductive film with a high transmittance and low specific resistance is obtained by optimizing the H₂ gas introduction amount in the process of introducing the H₂ gas.

According to the forming method for a transparent electrically conductive film of the present embodiment, it is possible to lower the specific resistance of a zinc oxide-based transparent electrically conductive film and maintain transparency with respect to visible light rays by performing sputtering in reactive gas atmosphere that include two types or more that are selected from the group of hydrogen gas, oxygen gas, and water vapor.

Accordingly, it is possible to readily form a zinc oxide-based transparent electrically conductive film in which the specific resistance is low and having excellent transparency with respect to visible light rays.

In particular, in the case of wanting to change the peak wavelength of transmittance, it is possible to significantly change the shift amount of the peak by the introduction of water vapor. Moreover, adjustment of the shift amount is also possible by the introduction of oxygen or hydrogen.

Also, in the case of particularly seeking to achieve transmittance and low resistance at a high level, it is preferable to introduce oxygen and hydrogen.

According to the film forming apparatus for a transparent electrically conductive film of the present embodiment, the gas introduction unit 15 is constituted with the sputtering gas introduction unit 15a that introduces sputtering gas such as argon, the hydrogen gas introduction unit 15b that introduces hydrogen gas, the oxygen gas introduction unit 15c that introduces oxygen gas, and the water vapor introduction unit 15d that introduces water vapor in optimum conditions. For that reason, it is possible to make the atmosphere when forming a zinc oxide-based transparent electrically conductive film a reactive gas atmosphere in which the ratio of the reducing gas and the oxidizing gas is balanced.

Accordingly, just by modifying a portion of a conventional film forming apparatus, it is possible to form a zinc oxide-based transparent electrically conductive film with low specific resistance and excellent transparency with respect to visible light rays.

### Second Embodiment

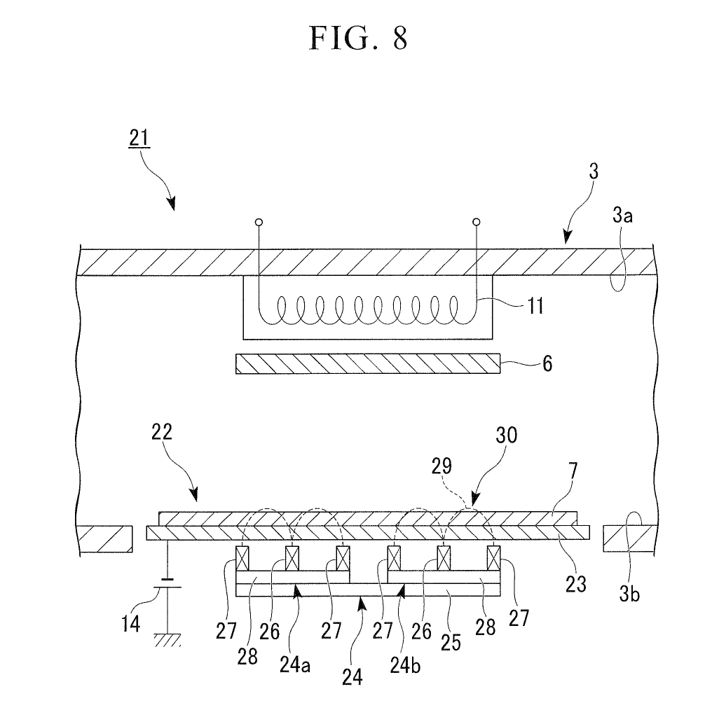

FIG. 8 is a plan cross-sectional view that shows the essential portions of the film forming chamber of an interback-type magnetron sputtering apparatus of the second embodiment of the present invention.

A magnetron sputtering apparatus 21 differs from the aforementioned sputtering apparatus 1 on the points of holding the target 7 of a zinc oxide-based material on one side surface 3b of the film forming chamber 3, and a longitudinally-installed sputtering cathode mechanism (target holding unit) 22 that generates a desired magnetic field being provided.

The sputtering cathode mechanism 22 is provided with a back plate 23 that is bonds (fixes) the target 7 with a brazing material or the like, and a magnetic circuit (magnetic field generating unit) 24 that is disposed along the rear surface of the back plate 23. This magnetic circuit 24 generates a horizontal magnetic field on the front surface of the target 7. The magnetic circuit 24 is provided a plurality of magnetic circuit units (two in FIG. 8) 24a, 24b and a bracket 25 that couples and unifies these magnetic circuit units 24a, 24b. These magnetic circuit units 24a, 24b are each provided with a first magnet 26 and a second magnet 27 whose polarities at the surface on the back plate 23 side mutually differ, and a yoke 28 on which they are fitted.

In this magnetic circuit 24, a magnetic field is expressed by magnetic lines of force 29 is generated by the first magnet 26 and the second magnet 27 whose polarities mutually differ on the back plate 23 side. Thereby, a position 30 appears at which the vertical magnetic field becomes 0 (the horizontal magnetic field is a maximum) at a region corresponding to the space of the first magnet 26 and the second magnet 27 on the surface of the target 7. Since high density plasma is generated at this position 30, and it is possible to improve the film forming speed.

The maximum value of the strength of the horizontal magnetic field on the surface of this target 7 is preferably 600 Gauss or more. By making the maximum value of the strength of the horizontal magnetic field 600 Gauss or more, it is possible to lower the discharge voltage.

The film forming apparatus for a transparent electrically conductive film of the present embodiment exhibits the same effect as the sputtering apparatus of the first embodiment.

Moreover, since the sputtering cathode 22 that generates a desired magnetic field is longitudinally provided on the one side surface 3b of the film forming chamber 3, it is possible form a zinc oxide-based transparent electrically conductive film with an organized lattice by making the sputtering voltage 340 V or less and the maximum value of the horizontal magnetic field strength on the surface of the target 7,600 Gauss or more.

In this zinc oxide-based transparent electrically conductive film, oxidation is hindered even if annealing is performed at a high temperature after film formation, and it is possible to inhibit increases in the specific resistance. Moreover, it is possible to obtain a zinc oxide-based transparent electrically conductive film with excellent heat resistance.

### INDUSTRIAL APPLICABILITY

The film forming method and film forming apparatus for a transparent electrically conductive film of the present invention can lower the specific resistance of a zinc oxide-based transparent electrically conductive film and maintain the transparency with respect to visible light rays.

What is claimed is:

1. A film forming method for a transparent electrically conductive film that forms a zinc oxide-based transparent electrically conductive film on a substrate by sputtering using a target containing a zinc oxide-based material,
performing the sputtering in a reactive gas atmosphere that contains two types or three types selected from among a group consisting of hydrogen gas, oxygen gas and water vapor, wherein when performing the sputtering, in the case of including at least the hydrogen gas and the oxygen gas in the atmosphere, a ratio R (=P_{H2}/P_{O2}) of the partial pressure of the hydrogen gas (P_{H2}) to the partial pressure of the oxygen gas (P_{O2}) satisfies Equation (1) below.
15≦(R=P_{H2}/P_{O2})≦5 (1)

2. (canceled)

3. The film forming method for a transparent electrically conductive film according to claim 1, wherein when performing the sputtering, the sputtering voltage that is applied to the target is 340 V or less.

4. The film forming method for a transparent electrically conductive film according to claim 1, wherein when performing the sputtering, a sputtering voltage composed of a high frequency voltage superimposed on a direct current voltage is applied to the target.

5. The film forming method for a transparent electrically conductive film according to claim 1, wherein when performing the sputtering, the maximum value of the strength of the horizontal magnetic field at the surface of the target is 600 Gauss or more.

6. The film forming method for a transparent electrically conductive film according to claim 1, wherein the zinc oxide-based material is aluminum-doped zinc oxide or gallium-doped zinc oxide.

7. A film forming apparatus for a transparent electrically conductive film that forms a zinc oxide-based transparent electrically conductive film on a substrate by sputtering using a target containing a zinc oxide-based material, comprising:
a vacuum container;
at least two of a hydrogen gas introduction unit, an oxygen gas introduction unit, and a water vapor introduction unit that are provided in this vacuum container;
a target holding unit that holds the target in the vacuum container; and
a power supply that applies a sputtering voltage to the target.

8. The film forming apparatus for a transparent electrically conductive film according to claim 7, wherein the power supply serves as a direct current power supply and a high frequency power supply.

9. The film forming apparatus for a transparent electrically conductive film according to claim 7, wherein the target holding unit is provided with a magnetic field generating unit that generates a horizontal magnetic field of which the maximum value of the strength at the surface of the target is 600 Gauss or more.
